(19) United States
(12) Patent Application Publication
(10) Pub. No.: US 2024/0234654 A1
(43) Pub. Date: Jul. 11, 2024

(54) DISPLAY MODULE AND WEARABLE ELECTRONIC DEVICE INCLUDING THE SAME

(71) Applicant: SAMSUNG ELECTRONICS CO., LTD., Suwon-si (KR)

(72) Inventors: Hoyoung Jung, Suwon-si (KR); Nari Kim, Suwon-si (KR); Kyongtae Park, Suwon-si (KR); Keunsik Lee, Suwon-si (KR)

(73) Assignee: SAMSUNG ELECTRONICS CO., LTD., Suwon-si (KR)

(21) Appl. No.: 18/444,194

(22) Filed: Feb. 16, 2024

Related U.S. Application Data
(63) Continuation of application No. PCT/KR22/12066, filed on Aug. 12, 2022.

(30) Foreign Application Priority Data
Sep. 27, 2021 (KR) 10-2021-0127045

(51) Int. Cl. H01L 33/60; H01L 25/075

(52) U.S. Cl. CPC H01L 33/60; H01L 25/0753

(57) ABSTRACT

A display module includes: a substrate; a plurality of light emitting diodes mounted on a surface of the substrate; a partition wall formed on a surface of the substrate and configured to form a plurality of cells surrounding each of the plurality of light emitting diodes; a reflective layer formed on each of the plurality of cells, the reflective layer comprising a light exit portion forming an opening of each of the plurality of cells; and a micro-lens disposed at a location corresponding to the light exit portion and configured to concentrate light emitted from the light exit portion, wherein a width of the light exit portion may be less than a width of a space formed by the partition wall.

### CROSS-REFERENCE TO RELATED APPLICATIONS

This application is a continuation of International Application No. PCT/KR2022/012066, filed on Aug. 12, 2022, which is based on and claims priority to Korean Patent Application No. 10-2021-0127045, filed on Sep. 27, 2021, in the Korean Intellectual Property Office, the disclosures of which are incorporated by reference herein in their entireties.

### BACKGROUND

### 1. Field

The disclosure relates to a display module and a wearable electronic device including the same.

### 2. Description of the Related Art

An electronic device for a portability purpose generally includes a flat type display device and a battery, and has a bar type, a folder type, and a sliding type appearance. Recently, as electronic communication technology is developed, an electronic device has been miniaturized so that a wearable electronic device that may be worn on a part of a human body, such as a wrist or a head, and has been commercialized.

A wearable electronic device has a shape such as a watch or glasses, thus is portable, and various functions such as a mobile communication terminal are incorporated inside the miniaturized device, thereby satisfying consumers' needs.

The augmented reality (AR) glass worn on the head similar to the shape of glasses in the wearable electronic device includes a small display on which a plurality of light emitting diodes are mounted. The light emitting diode has a Lambertian emission angle characteristic of spreading in all directions.

However, the effective light amount of the light emitting diode transmitted to the diffraction optical system of the AR glass through a projection lens included in the AR glass is only an extremely small portion (e.g., approximately 6% or less of the total amount of light) out of the total amount of light. Accordingly, the related-art AR glass has a low brightness of the light emitting device, and thus it is difficult to clearly display an image or a video.

### SUMMARY

Additional aspects will be set forth in part in the description which follows and, in part, will be apparent from the description, or may be learned by practice of the presented embodiments.

According to an aspect of the disclosure, a display module includes: a substrate; a plurality of light emitting diodes mounted on a surface of the substrate; a partition wall formed on a surface of the substrate and configured to form a plurality of cells surrounding each of the plurality of light emitting diodes; a reflective layer formed on each of the plurality of cells, the reflective layer comprising a light exit portion forming an opening of each of the plurality of cells; and a micro-lens disposed at a location corresponding to the light exit portion and may be configured to concentrate light emitted from the light exit portion, wherein a width of the light exit portion may be less than a width of a space formed by the partition wall.

The center of the light exit portion and the center of the micro-lens may be coaxially disposed.

The center of the light exit portion may be deflected with respect to the center of the micro-lens.

The center of each light emitting diode of the plurality of light emitting diodes and the center of the micro-lens may be coaxially disposed.

The center of each light emitting diode of the plurality of light emitting diodes and the center of the light exit portion may be coaxially disposed.

The display module may further include a first optical layer disposed in a space formed by the reflective layer, and a second optical layer disposed between the micro-lens and the partition wall.

The display module may further include a color conversion layer disposed in a space formed by the reflective layer, and an optical layer disposed between the micro-lens and the partition wall.

The display module may further include a color filter layer, wherein the color conversion layer may be exposed by the light exit portion, and the color filter layer may be disposed on an upper surface of the color conversion layer corresponding to the light exit portion.

The reflective layer may include: a lower reflective layer disposed on an upper surface of the substrate; a side reflective layer disposed on a side surface of the partition wall; and an upper reflective layer which may be configured to form the light exit portion.

The upper layer may be disposed at a height corresponding to an opening of a cell of the plurality of cells.

The upper reflective layer may upwardly protrude toward the micro-lens, and the light exit portion may be disposed at a location higher than the height of the opening of a cell of the plurality of cells

The upper reflective layer may downwardly protrude toward the a light emitting diode of the plurality of light emitting diodes, and the light exit portion may be disposed at a location lower than the height of the opening of a cell of the plurality of cells.

The upper reflective layer may be disposed at a location lower than the opening of a cell of the plurality of cells.

The plurality of cells may comprise a plurality of sub-pixel structures constituting a pixel unit, and each of the light emitting diodes of the plurality of light emitting diodes may be respectively disposed in the plurality of sub-pixel structures and may be configured to emit light of different colors.

Each of the light emitting diodes of the plurality of light emitting diodes may be respectively disposed in the plurality of sub-pixel structures are configured to emit light of a same color, and a part of the plurality of sub-pixel structures may further include a color conversion layer which may be configured to convert color of the light emitted from each light emitting diode of the plurality of light emitting diodes

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a configuration of a wearable electronic device in a network environment according to one or more embodiments of the disclosure;

FIG. 2 is a diagram illustrating a structure of a wearable electronic device according to one or more embodiments of the disclosure;

FIG. 3 is a cross-sectional view illustrating a pixel structure of a display module according to one or more embodiments of the disclosure;

FIG. 4 is a diagram illustrating a state in which light is concentrated and emitted forward by a sub-pixel structure of a display module according to one or more embodiments of the disclosure;

FIG. 5 is a diagram illustrating a relationship between a focal length of a micro-lens, an interval between a micro-lens and a light exit portion, and a width of a light exit portion in a sub-pixel structure of a display module according to one or more embodiments of the disclosure;

FIG. 6 is a flowchart illustrating a process of manufacturing a sub-pixel structure of a display module according to one or more embodiments of the disclosure;

FIG. 7A is a view illustrating respective manufacturing processes of a sub-pixel structure of a display module according to one or more embodiments of the disclosure;

FIG. 7B is a view illustrating respective manufacturing processes of a sub-pixel structure of a display module according to one or more embodiments of the disclosure;

FIG. 7C is a view illustrating respective manufacturing processes of a sub-pixel structure of a display module according to one or more embodiments of the disclosure;

FIG. 7D is a view illustrating respective manufacturing processes of a sub-pixel structure of a display module according to one or more embodiments of the disclosure;

FIG. 7E is a view illustrating respective manufacturing processes of a sub-pixel structure of a display module according to one or more embodiments of the disclosure;

FIG. 7F is a view illustrating respective manufacturing processes of a sub-pixel structure of a display module according to one or more embodiments of the disclosure;

FIG. 7G is a view illustrating respective manufacturing processes of a sub-pixel structure of a display module according to one or more embodiments of the disclosure;

FIG. 7H is a view illustrating respective manufacturing processes of a sub-pixel structure of a display module according to one or more embodiments of the disclosure;

FIG. 8 is a schematic diagram illustrating a display module and a projection lens according to one or more embodiments of the disclosure;

FIG. 9 is an enlarged view illustrating the LC portion shown in FIG. 8 according to one or more embodiments of the disclosure;

FIG. 10 is an enlarged view showing the LL portion shown in FIG. 8 according to one or more embodiments of the disclosure;

FIG. 11 is an enlarged view illustrating the LR portion shown in FIG. 8 according to one or more embodiments of the disclosure;

FIG. 12 is a cross-sectional view illustrating a sub-pixel structure of a display module according to one or more embodiments of the disclosure;

FIG. 13 is a cross-sectional view illustrating a sub-pixel structure of a display module according to one or more embodiments of the disclosure;

FIG. 14 is a cross-sectional view illustrating a sub-pixel structure of a display module according to one or more embodiments of the disclosure;

FIG. 15 is a cross-sectional view illustrating a sub-pixel structure of a display module according to one or more embodiments of the disclosure;

FIG. 16 is a cross-sectional view illustrating a sub-pixel structure of a display module according to one or more embodiments of the disclosure;

FIG. 17 is a cross-sectional view illustrating a sub-pixel structure of a display module according to one or more embodiments of the disclosure;

FIG. 18 is a cross-sectional view illustrating a sub-pixel structure of a display module according to one or more embodiments of the disclosure;

FIG. 19 is a cross-sectional view illustrating a sub-pixel structure of a display module according to one or more embodiments of the disclosure;

FIG. 20 is a cross-sectional view illustrating a sub-pixel structure of a display module according to one or more embodiments of the disclosure;

FIG. 21 is a cross-sectional view illustrating a structure of a pixel unit of a display module according to one or more embodiments of the disclosure;

FIG. 22 is a cross-sectional view illustrating a structure of a pixel unit of a display module according to one or more embodiments of the disclosure;

FIG. 23 is a cross-sectional view illustrating a structure of a pixel unit of a display module according to one or more embodiments of the disclosure; and

FIG. 24 is a cross-sectional view illustrating a structure of a pixel unit of a display module according to one or more embodiments of the disclosure;

### DETAILED DESCRIPTION

The embodiments described herein are example embodiments, and thus, the disclosure is not limited thereto and embodiments may include various modifications, equivalents, and/or alternatives.

The terms used in the disclosure will be briefly explained, and one or more embodiments will be described in greater detail with reference to the accompanying drawings. In describing the disclosure, a detailed description of a related known technology may be omitted, and a duplicate description of the same configuration may be omitted.

Terms used in the disclosure are selected as general terminologies currently widely used in consideration of the configuration and functions of the disclosure, but may be different depending on intention of those skilled in the art, a precedent, appearance of new technologies, or the like. Further, in specific cases, terms may be arbitrarily selected. In this example, the meaning of the terms will be described in the description of the corresponding embodiments. Accordingly, the terms used in the description should not necessarily be construed as simple names of the terms, but be defined based on meanings of the terms and overall contents of the disclosure.

The one or more embodiments may vary, and may be provided in different example embodiments. Various example embodiments will be described with reference to accompanying drawings. However, this does not necessarily limit the scope of the one or more embodiments to a specific embodiment form. Instead, various modifications, equivalents and replacements included in the disclosed concept and technical scope of this disclosure may be employed. While describing the one or more embodiments, if it is determined that the specific description regarding a known technology obscures the gist of the disclosure, the specific description may be omitted.

The term such as “first” and “second” used in the one or more embodiments may modify refer to elements regardless of an order and/or importance of the corresponding elements, and does not limit the corresponding elements. The terms are simply used to differentiate one component from other components. For example, the ‘first’ component may be named the ‘second’ component, and vice versa, without departing from the scope of the disclosure.

Singular forms are intended to include plural forms unless the context clearly indicates otherwise. The terms “include”, “comprise”, “is configured to,” etc., of the description are used to indicate that there are features, numbers, steps, operations, elements, parts or combination thereof, and they should not exclude the possibilities of combination or addition of one or more features, numbers, steps, operations, elements, parts or a combination thereof.

In the disclosure, a ‘module’ or a ‘unit’ performs at least one function or operation and may be implemented by hardware or software or a combination of the hardware and the software. In addition, a plurality of ‘modules’ or ‘units’ may be integrated into at least one module and may be realized as at least one processor in an integrated manner except for ‘modules’ or ‘units’ that should be realized in specific hardware.

Hereinafter, the disclosure will be described in greater detail with reference to the accompanying drawings. However, the disclosure may be implemented in various different forms and is not limited to the embodiments described herein. In addition, in order to clearly describe the disclosure, portions not related to the description may be omitted, and like reference numerals are assigned to similar parts throughout the disclosure.

Furthermore, one or more embodiments of the disclosure are described in greater detail with reference to the accompanying drawings and the contents disclosed in the accompanying drawings, but the disclosure is not limited or restricted by the embodiments.

Hereinafter, with reference to the drawings, a wearable electronic device according to various example embodiments of the disclosure will be described in greater detail.

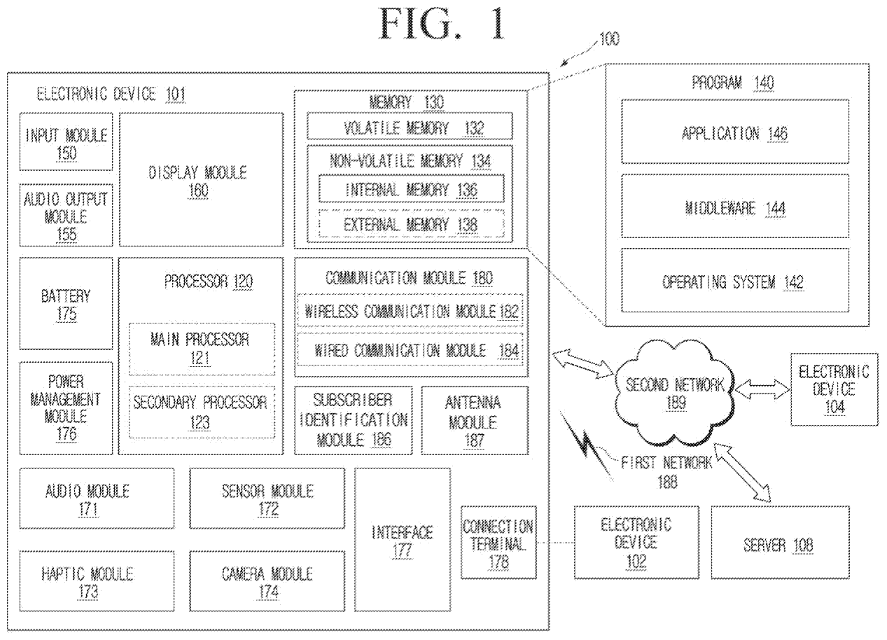

FIG. 1 is a block diagram illustrating configuration of a wearable electronic device in a network environment according to one or more embodiments. For reference, although a device according to one or more embodiments of the disclosure is referred to as an “electronic device” for convenience of description, the device of one or more embodiments may be an electronic device, a wireless communication device, a display device, or a portable communication device.

Referring to FIG. 1, a wearable device 101 in a network environment 100 may communicate with an electronic device 102 via a first network 188 (e.g., a short-range wireless communication network) or communicate with an electronic device 104 or a server 108 via a second network 189 (e.g., wide area network). According to one or more embodiments, the wearable electronic device 101 may communicate with the electronic device 104 via the server 108. According to one or more embodiments, the wearable electronic device 101 may include a processor 120, a memory 130, an input module 150, an audio output module 155, a display module 160, an audio module 171, a sensor module 172, a haptic module 173, a camera module 174, a battery 175, a power management module 176, an interface 177, a connection terminal 178, a communication module 180, a subscriber identification module 186, or an antenna module 187.

According to one or more embodiments, at least one (e.g., the connection terminal 178) of the components may be omitted from the wearable electronic device 101, or one or more other components may be added to the wearable electronic device 101. According to one or more embodiments, some of the components (e.g., the sensor module 172, the camera module 174, or the antenna module 187) may be integrated into one component (e.g., the display module 160).

According to one or more embodiments, the wearable electronic device 101 may display various images. The image may refer to a concept including a still image and a moving image, and the wearable electronic device 101 may display various images such as broadcast content, multimedia content, and the like. In addition, the wearable electronic device 101 may display a user interface (UI) and an icon. The display module 160 may include a display deriver IC and may display an image based on an image signal received from the processor 120. The display driver IC may generate a drive signal for a plurality of sub-pixels based on an image signal received from the processor 120, and display an image by controlling light emission of the plurality of sub-pixels based on the drive signal.

According to one or more embodiments, the processor 120 may control the overall operation of the wearable electronic device 101. The processor 120 may be configured with one or multiple processors. The processor 120 may perform an operation of the wearable electronic device 101 according to one or more embodiments of the disclosure by executing at least one instruction stored in the memory.

According to an embodiment, the processor 120 may be implemented by a digital signal processor (DSP) that processes a digital image signal, a microprocessor, a GPU, an artificial intelligence (AI) processor, a neural processing unit (NPU), or a time controller (TCON). However, the processor 120 is not limited thereto, and may include one or more of a central processing unit (CPU), a micro controller unit (MCU), a micro processing unit (MPU), a controller, an application processor (AP), a communication processor (CP), and an advanced reduced instruction set computer (RISC) machine (ARM) processor, or may be defined by these terms. In addition, the processor 120 may be implemented by a system-on-chip (SoC) or a large scale integration (LSI) in which a processing algorithm is embedded or may be implemented in the form of an application specific integrated circuit (ASIC) or a field programmable gate array (FPGA).

According to one or more embodiments, the processor 120 may drive an operating system or an application program to control hardware or software components connected to the processor 120, and may perform various types of data processing and computation. In addition, the processor 120 may load and process a command or data received from at least one of other components into a volatile memory, and store various data in a non-volatile memory.

According to one or more embodiments, the processor 120 may control the at least one another component (e.g., hardware or software component) of the wearable electronic device 101 connected to the processor 120 by executing the software (e.g., the program 140) and perform various data processing or operation. According to one or more embodiments, as at least a part of the data processing or operation, the processor 120 may store the command or data received from another component (e.g., the sensor module 172 or the communication module 180) to a volatile memory 132, process command or data stored in the volatile memory 132, and store the result data in a non-volatile memory 134. According to one or more embodiments, the processor 120 may include a main processor 121 (e.g., a central processing unit or an application processor), and a secondary processor 123 (e.g., a graphics processing unit, a neural processing unit (NPU), an image signal processor, a sensor hub processor, or a communication processor) which may be operated together or independently. In state in which the wearable electronic device 101 includes the main processor 121 and the secondary processor 123, the secondary processor 123 may use less power than the main processor 121, or may be set to be specialized to a designated function. The secondary processor 123 may be implemented separately from, or as a part of, the main processor 121.

According to one or more embodiments, the secondary processor 123 may, in a state in which the main processor 121 is in an inactive state (for example: sleep) or in an active state (for example: execution of an application), control a part of the functions or states related to at least one component (for example: display module 160, the sensor module 172, or the communication module 180) among the components of the electronic device 101. According to one or more embodiments, the secondary processor 123 (e.g., an image signal processor or a communication processor) may be implemented as a part of a functionally related other components (e.g., camera module 174 or communication module 180). According to one or more embodiments, the secondary processor 123 (e.g., a neural network processing device) may include a hardware structure specialized for processing an artificial intelligence model. The artificial intelligence model may be generated through machine learning. The learning may be performed by an electronic device 101 in which an artificial intelligence model is performed, and may be performed through a separate server (for example, the server 108). The learning algorithm may include supervised learning, unsupervised learning, semi-supervised learning, or reinforcement learning, but is not limited thereto. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more of the above. The artificial intelligence model may additionally or alternatively include a software structure in addition to the hardware structure.

According to one or more embodiments, the memory 130 may store various data used by at least one component (e.g., processor 120 or sensor module 172) of the wearable electronic device 101. The data may include software (e.g., program 140) and input data or output data related with software instructions. The memory 130 may include the volatile memory 132 or non-volatile memory 134.

According to one or more embodiments, the processor 120 may be stored in the memory 130 as software, and include an operating system 142, middleware 144, or an application 146.

According to one or more embodiments, the input module 150 may receive a command or data to be used by a component (e.g., the processor 120) of the wearable electronic device 101 from the outside (e.g., a user) of the wearable electronic device 101. The input module 150 may further include a microphone, a dome switch, a touch pad (a contact capacitive type, a pressure resistive type, an infrared sensing method, a surface ultrasonic conduction method, an integral tension measuring method, a piezo effect method, etc.), but is not limited thereto.

According to one or more embodiments, the sound output module 155 may output an acoustic signal to the outside of the wearable electronic device 101. The sound output module 155 may include a speaker or a receiver. The speaker may be used for general purposes, such as multimedia playback or recording playback. The receiver may be used to receive an incoming call. According to one or more embodiments, the receiver may be implemented as separate from, or as part of a speaker.

According to one or more embodiments, the display module 160 may visually provide information to the outside (e.g., a user) of the wearable electronic device 101. The display module 160 may include a display, a hologram device, or a projector and a control circuit for controlling a corresponding device.

According to one or more embodiments, the audio module 171 may convert a sound into an electrical signal or convert the electrical signal to sound. According to one or more embodiments, the audio module 171 may obtain a sound through the input module 150, or output the sound through the sound output module 155, or an external electronic device (e.g., an electronic device 102) (e.g., a speaker or a headphone) directly or wirelessly connected to or the wearable electronic device 101.

According to one or more embodiments, the sensor module 172 may detect an operation state (e.g., power or temperature) of the wearable electronic device 101 or an environmental state (e.g., a state of a user) external to the wearable electronic device 101, and generate an electrical signal or a data value corresponding to the detected state. According to one or more embodiments, the sensor module 172 may include a terrestrial magnetic sensor, an acceleration sensor, a location sensor, and a gyroscope sensor. In addition, sensors for detecting biological signals such as a user's biometric signal, such as an Electrocardiography (ECG), Galvanic skin reflex (GSR), pulse wave, and the like may be provided. In addition, one or more embodiments may further include a temperature sensor, a humidity sensor, an infrared sensor, an atmospheric pressure sensor, a proximity sensor, a magnetic sensor, a grip sensor, a color sensor, an illuminance sensor, and the like, but is not limited thereto.

According to one or more embodiments, the haptic module 173 may convert an electrical signal into a mechanical stimulus (e.g., a vibration or a movement) or an electrical stimulus which may be recognized by a user through tactile sensation or kinesthetic sensation. According to one or more embodiments, the haptic module 173 may include a motor, a piezoelectric element, or an electric stimulator.

According to one or more embodiments, the camera module 174 may capture a still image and a moving image. According to one or more embodiments, the camera module 174 may include one or more lenses, image sensors, image signal processors, or flashes.

According to one or more embodiments, the power management module 176 may manage power supplied to the wearable electronic device 101. According to one or more embodiments, the power management module 176 may be implemented as at least part of a power management integrated circuit (PMIC).

According to one or more embodiments, the battery 175 may supply power to at least one component of the electronic device 101. According to one or more embodiments, the battery 175 may include a primary cell which is not rechargeable, a secondary cell which is rechargeable, or a fuel cell.

According to one or more embodiments, the interface 177 may support one or more specified protocols to be used for the wearable electronic device 101 to be connected to the external electronic device (e.g., the electronic device 102) directly or wirelessly.

According to one or more embodiments, the connection terminal 178 may include a connector through which the wearable electronic device 101 may be physically connected to an external electronic device (e.g., the electronic device 102).

According to one or more embodiments, the communication module 180 may support establishment of direct (e.g.: wired) communication channel between the electronic device 101 and an external electronic device (e.g., electronic device 102, electronic device 104, or server 108) or wireless communication channel, and communication through the established communication channels. The communication module 180 may include one or more communication processors which are operated independently of the processor 120 (e.g., application processor) and support direct (e.g., wired) communication or wireless communication. According to one or more embodiments, the communication module 180 may include a wireless communication module 182 (e.g., cellular communication module, near field wireless communication module, or global navigation satellite system (GNSS) communication module) or wired communication module 184 (e.g., local area network (LAN) communication module, or power line communication module). The corresponding communication module among these communication modules may communicate with an external electronic device 104 via the first network 188 (e.g., Bluetooth, Wi-Fi direct or near field communication network such as infrared data association (IrDA)) or the second network 189 (e.g., legacy cellular network, 5G network, next generation communication network, Internet, or computer network (e.g., LAN or WAN)). These types of communication modules may be incorporated into one component (e.g., a single chip) or implemented with a plurality of components (e.g., a plurality of chips) that are separate from each other. The wireless communication module 182 may confirm and authenticate the wearable electronic device 101 in the communication network such as the first network 188 or the second network 189 using the subscriber information (e.g., international mobile subscriber identity (IMSI)) stored in the subscriber identification module 186.

According to one or more embodiments, the wireless communication module 182 may support a 5G network after a 4G network and a next generation communication technology, such as a new radio (NR) access technology. The NR access technology may support high-speed data transmission (enhanced mobile broadband (eMBB)) of high-capacity data, minimization/reduction of terminal power, massive machine type communications (mMTC), or ultra-reliable and low-latency communications (URLLC). The wireless communication module 182 may support a high frequency band (e.g., an mmWave band) for achieving a high data transmission rate. The wireless communication module 182 may support various technologies for ensuring performance in a high-frequency band, such as beamforming, massive multiple-input and multiple-output (MIMO), full dimensional MIMO (FD-MIMO), array antenna, analog beam-forming, or large scale antenna. The wireless communication module 182 may support various requirements specified in the wearable electronic device 101, an external electronic device (e.g., the electronic device 104), or a network system (e.g., the second network 189). According to one or more embodiments, the wireless communication module 182 may support a peak efficient data rate (for example, 20 Gbps or more) for eMBB realization, a loss coverage specification (for example, 164 dB or less) for realization of mMTC, or U-plane latency (e.g., 0.5 ms or less for down link (DL) and uplink (UL), or round trip 1 ms or less) for URLLC realization.

According to one or more embodiments, the antenna module 187 may transmit a signal or power to an external device (e.g., an external electronic device) or receive a signal or power from the outside. According to one or more embodiments, the antenna module 187 may include one or more antennas (e.g., array antenna), and at least one antenna suitable for a communication method used in a communication network, such as the first network 188 or the second network 189, may be selected from the one or more antennas by the communication module 180.

According to one or more embodiments, the antenna module 187 may include a plurality of antennas (e.g., an array antenna), and according to one or more embodiments, the antenna module 187 may include an antenna including a radiator including a conductive pattern or a conductor formed on a substrate (e.g., PCB).

According to one or more embodiments, the antenna module 187 may form an mmWave antenna module. According to one or more embodiments, the mmWave antenna module may include a printed circuit board, a radio frequency integrated circuit (RFIC) disposed on or adjacent to a first surface (e.g., a lower surface) of the printed circuit board and capable of supporting a designated high frequency band (e.g., an mmWave band), and a plurality of antennas (e.g. an array antenna) disposed on or adjacent to a second surface (e.g., an upper surface or a side surface) of the printed circuit board and capable of transmitting or receiving a signal of the designated high frequency band.

A signal or power may be transmitted or received between the communication module 180 and an external electronic device via at least one antenna. According to one or more embodiments, another component (e.g., a radio frequency integrated circuit (RFIC)) other than the radiator may be additionally formed as a part of the antenna module 187.

At least a part of the components may be interconnected through the communication method (e.g., bus, general purpose input and output (GPIO), serial peripheral interface (SPI), or mobile industry processor interface (MIPI)) among peripheral devices and exchange a signal (e.g., command or data) from each other.

An instruction or data may be transmitted or received between the wearable electronic device 101 and the external electronic device 104 via the server 108 connected to the second network 189. Each of the external electronic devices 102, 104 may be a device of a same type as or a different type from the wearable electronic device 101. According to one or more embodiments, all or a part of operations to be executed at the wearable electronic device 101 may be executed by at least one external electronic device among external electronic devices 102, 104, or 108. In a state in which the wearable electronic device 101 should perform any function or service automatically, or in response to a request from a user or another device, the wearable electronic device 101 may request the one or more external electronic devices to perform at least part of the function or the service, instead of, or in addition to, executing the function or the service by itself. The one or more external electronic devices receiving the request may execute at least a part of the function or the service requested, or an additional function or service related to the request, and transfer a result of the execution to the wearable electronic device 101. The wearable electronic device 101 may provide the result, with or without further processing of the result, as at least part of a response to the request. For this a cloud computing, distributed computing, mobile edge computing (MEC), or client-server computing technology may be used. The wearable electronic device 101 may provide an ultra-low latency service using distributed computing or mobile edge computing. According to one or more embodiments, the external electronic device 104 may include an Internet of Things (IoT) device. The server 108 may be an intelligent server using machine learning and/or a neural network. According to one or more embodiments, the external electronic device 104 or the server 108 may be included in a second network 189. The wearable electronic device 101 may be applied to an intelligent service (for example, a smart home, a smart city, a smart car, or healthcare) based on the 5G communication technology and an IoT-related technology.

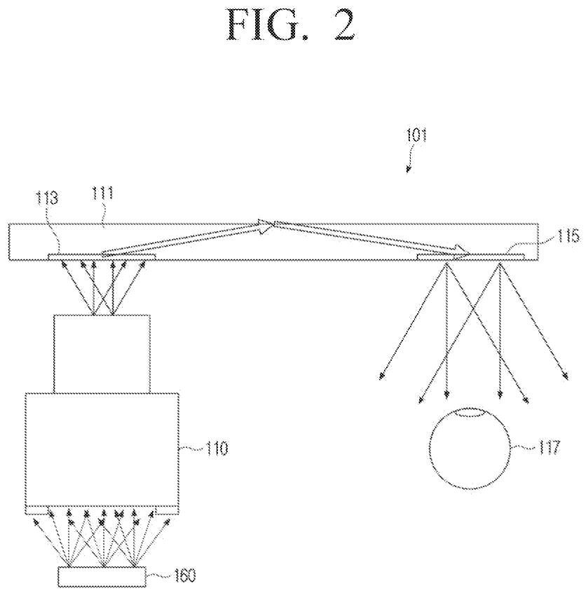

FIG. 2 is a diagram illustrating a structure of a wearable electronic device according to one or more embodiments.

Referring to FIG. 2, the wearable electronic device 101 according to one or more embodiments may include a display module 160, a projection lens 110 on which light emitted from a plurality of light emitting diodes mounted on the display module 160 is incident, and a diffraction optical member 111 to which the light concentrated by the projection lens 110 is incident.

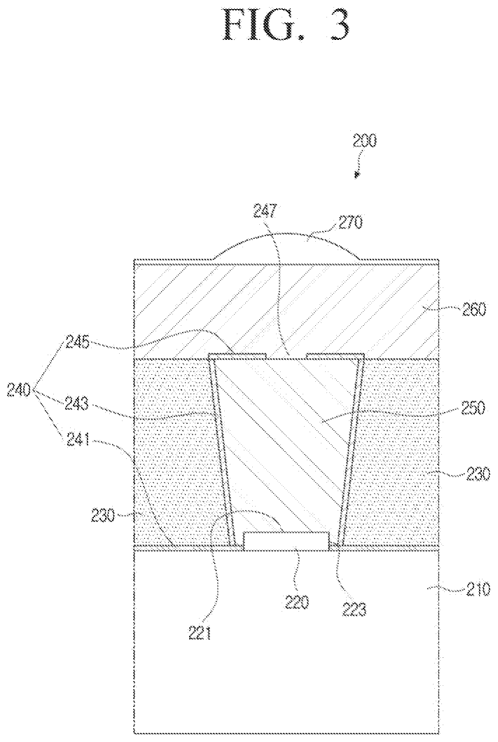

According to one or more embodiments, the light emitted from the display module 160 is concentrated through a micro-lens 270 (see FIG. 3), which will be described later, and is incident on the projection lens 110. The light incident on the projection lens 110 may be projected to the eyes of a user through the diffraction optical member 111.

According to one or more embodiments, the size of the display module 160 may be equal to or smaller than the size of the light incident surface of the projection lens 110. Light emitted from a plurality of light emitting diodes of the display module 160 is incident into the projection lens 110 through the light incident surface of the projection lens 110.

According to one or more embodiments, the diffraction optical member 111 may include an optical waveguide including a transparent material (e.g. glass). A first diffraction grating 113 and a second diffraction grating 115 may be disposed on one side and the other side of the diffraction optical member 111, respectively. The first diffraction grating 113 may be arranged to correspond to the emission surface of the projection lens 110, and the light emitted from the emission surface of the projection lens 110 is incident into the diffraction optical member 111. The second diffraction grating 115 emits the light passing through the inside of the diffraction optical member 111 to the outside of the diffraction optical member 111. The second diffraction grating 115 may be disposed at a location at which light is emitted toward the eyes 117 of the user while the user is wearing the wearable electronic device 101 on the head of the user.

According to one or more embodiments, a sub-pixel structure 200 (see FIG. 3) provided in the display module 160 of the disclosure may concentrate light emitted from the light emitting diodes 220 (LED's) (see FIG. 3) to a front surface without spreading widely. Most of the light emitted from each sub-pixel structure 200 of the display module 160 may be concentrated on the incident surface of the projection lens 110 without departing from the incident surface of the projection lens 110.

Hereinafter, the sub-pixel structure 200 according to one or more embodiments will be described with reference to the drawings.

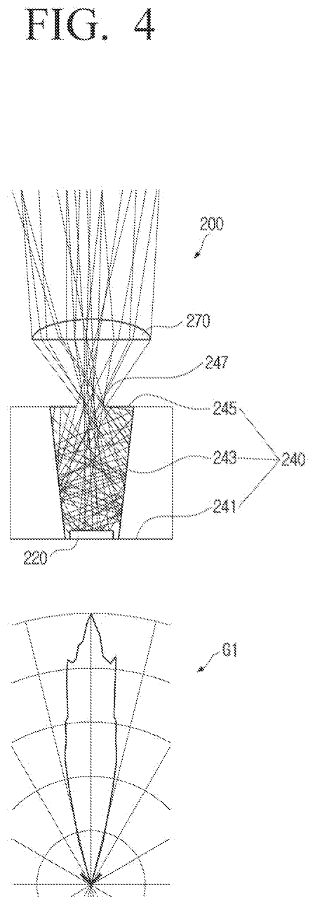

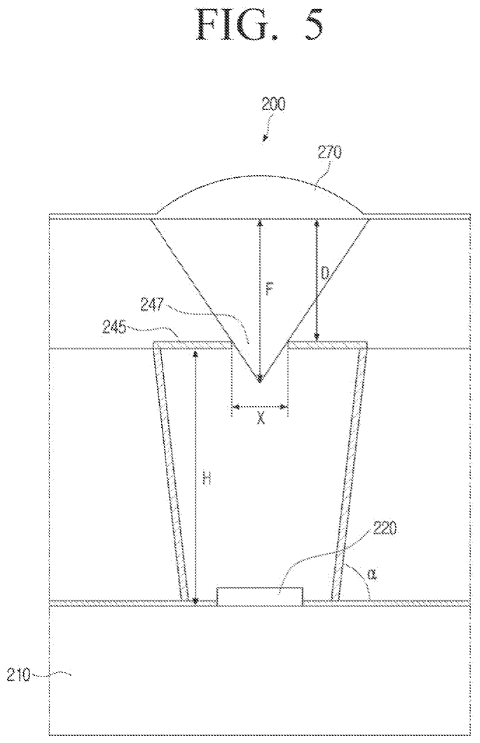

FIG. 3 is a cross-sectional view illustrating a sub-pixel structure of a display module according to one or more embodiments, FIG. 4 is a diagram illustrating a state in which light is concentrated and emitted forward by a sub-pixel structure of a display module according to an embodiment of the disclosure, FIG. 5 is a diagram illustrating a relationship between a focal length of a micro-lens, an interval between a micro-lens and a light exit portion, and a width of a light exit portion in a sub-pixel structure of a display module according to an embodiment of the disclosure.

Referring to FIG. 3, the display module 160 may include a substrate 210, a plurality of light emitting diodes 220 arranged on the substrate, and the micro-lens 270 configured to project light emitted from each light emitting diode to a light incident surface of the projection lens 110.

According to one or more embodiments, the substrate 210 comprises a transparent glass material (a main component is a SiO₂). However, the one or more embodiments are not limited thereto, and may be formed of a transparent or translucent polymer. The polymer may be an insulating organic material such as polyether sulfone (PES), polyimide (PI), polyethylene terephthalate (PET), polyethylene naphthalate (PEN), polycarbonate (PC), or the like.

According to one or more embodiments, a plurality of thin film transistors (TFT) are provided to the substrate 210. In this this closure, the TFT is not limited to a particular structure or type. The TFT of the disclosure may include a substrate that may be realized such as amorphous silicon (a-Si) TFT, low temperature polycrystalline silicon (LTPS) TFT, low temperature polycrystalline oxide (LTPO) TFT, hybrid oxide and polycrystalline silicon (HOP) TFT, liquid crystalline polymer (LCP) TFT, organic TFT (OTFT), graphene TFT, or the like.

According to one or more embodiments, the plurality of light emitting diodes 220 may be an inorganic light emitting device, such as a micro light emitting diode (LED) having a size of about 50 μm or less. According to one or more embodiments, the plurality of light emitting diodes 220 may be an inorganic light emitting diode and may be a micro LED having a size of about 3 μm or less. The micro LED may be a flip chip type in which both a positive electrode and a negative electrode are disposed on the opposite surface of the light emitting surface. However, the one or more embodiments are not limited thereto, and may include a lateral chip type or a vertical chip type. According to one or more embodiments, a light emitting diode applied to the substrate 210 may be an organic light emitting diode (OLED) without being limited to an inorganic light emitting diode.

According to one or more embodiments, the plurality of light emitting diode 220 may be arranged in a grating arrangement on the substrate 210, but are not limited thereto. However, it is not necessary that the arrangement of the plurality of light emitting diode 220 is a grating arrangement. A plurality of LEDs may be arranged in a pentile RGBG layout. The pentile RGBG layout is a layout in which the sub-pixels are arranged in such a way that the numbers of red, green, and blue sub-pixels are at a ratio of 1:1:2 (RGBG) based on a cognitive characteristic that a person identifies green better than blue. The pentile RGBG layout may enable an increase in yield and a reduction in unit cost, and enable implementation of a high resolution on a small screen, and thus is effective.

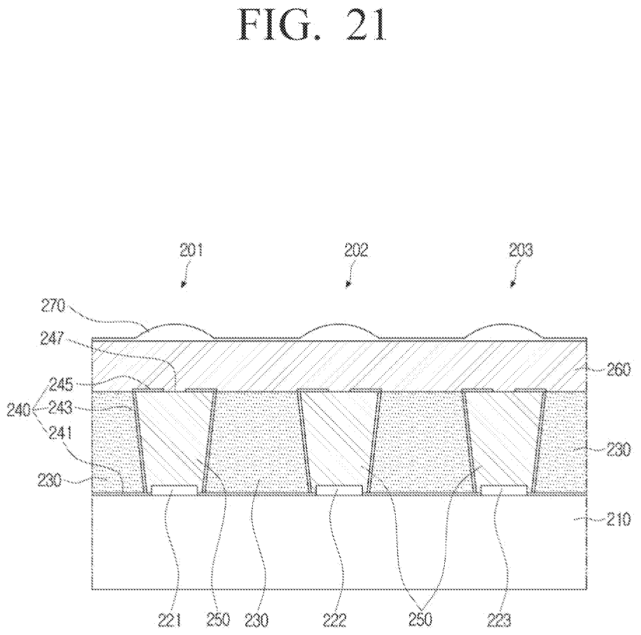

According to one or more embodiments, the plurality of light emitting diodes 220 include a plurality of pixels. One pixel may include a plurality of sub-pixels 201, 202, 203 (FIG. 21) that emit different light. Here, the reference numeral 201 is a sub-pixel for emitting blue light, the reference numeral 202 is a sub-pixel for emitting red light, and the reference numeral 203 may be a sub-pixel for emitting green light. Since one ‘sub-pixel’ and one ‘light emitting device’ refer to the same configuration, the ‘sub-pixel’ and the ‘light emitting device’ may be used interchangeably in the disclosure.

According to one or more embodiments, each light emitting diode 220 may include the first conductive layer, the second conductive layer, and the active layer disposed between the first semiconductor layer and the second conductive layer.

According to one or more embodiments, the first semiconductor layer, the active layer, and the second semiconductor layer may be formed using a method such as metal organic chemical vapor deposition (MOCVD), chemical vapor deposition (CVD), plasma-enhanced chemical vapor deposition (PECVD), or the like.

According to one or more embodiments, the first semiconductor layer may include a p-type semiconductor layer (anode, oxide electrode). The p-type semiconductor layer may be selected from GaN, AlN, AlGaN, InGaN, InN, InAlGaN, AlInN, or the like, and may be doped with a p-type dopant such as Mg, Zn, Ca, Sr, or Ba.

According to one or more embodiments, the second semiconductor layer may include, an n-type semiconductor layer (cathode, reduced electrode). The n-type semiconductor layer may be selected from, GaN, AlN, AlGaN, InGaN, InN, InAlGaN, AlInN, or the like, and may be doped with a n-type dopant such as Si, Ge, or Sn. In the meantime, the light emitting diode is not limited to the aforementioned configuration and the first semiconductor layer may include the n-type semiconductor layer and the second semiconductor layer may include the p-type semiconductor layer. The active layer is a region in which electrons and holes are recombined, and may transition to a low energy level by recombination of electrons and holes, and may generate light having a corresponding wavelength.

According to one or more embodiments, the active layer may include a semiconductor material such as amorphous silicon or poly crystalline silicon. The one or more embodiments are not limited thereto and may include an organic semiconductor material, and may be formed in a single quantum well (SQW) structure or a multi quantum well (MQW) structure.

According to one or more embodiments, each of the light emitting diodes 220 may have a first electrode and a second electrode arranged on the opposite surface of the light emitting surface 221. If the first electrode is a positive electrode, the second electrode may be a negative electrode. The first and second electrodes may be formed of Au or an alloy containing Au, but are not limited thereto.

According to one or more embodiments, each light emitting diode 220 may emit light to the light emitting surface 221 and a side surface 223 of the light emitting diode 220, respectively. A passivation layer for protecting the side surface 223 may be formed on the side surface 223 of the light emitting diode 220. When the passivation layer has low transparency and high reflectance, the amount of light emitted to the side surface 223 may be greatly reduced, and light emitted to the side surface 223 may be reflected by the passivation layer and emitted to the light emitting surface 221. According to one or more embodiments, the passivation layer may include an inorganic insulating film (e.g., silicon oxide (SiO₂)) and/or an organic insulating film (e.g., a general-purpose polymer (PMMA, PS)). The passivation layer may be formed in a composite laminated structure of an inorganic insulating film and an organic insulating film.

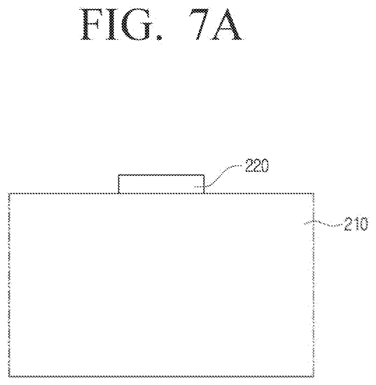

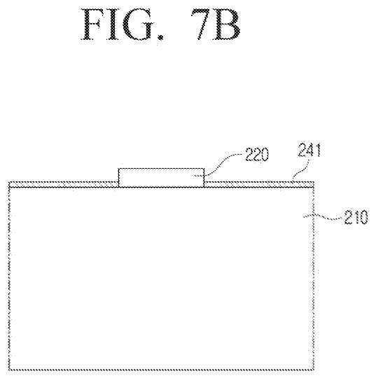

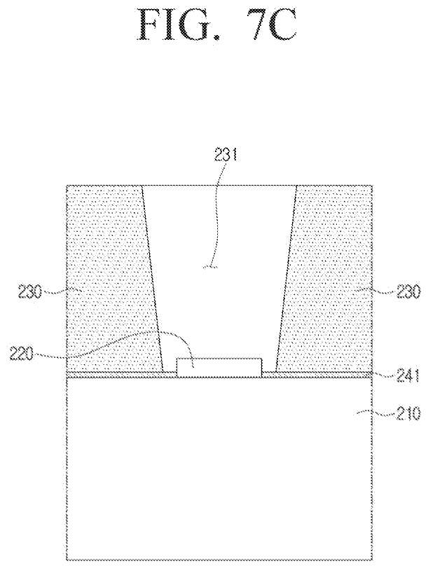

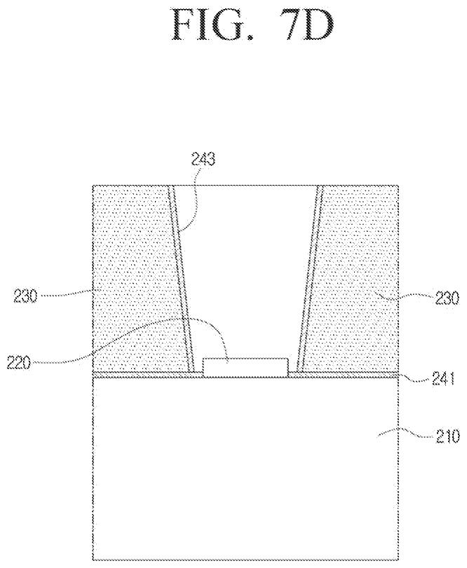

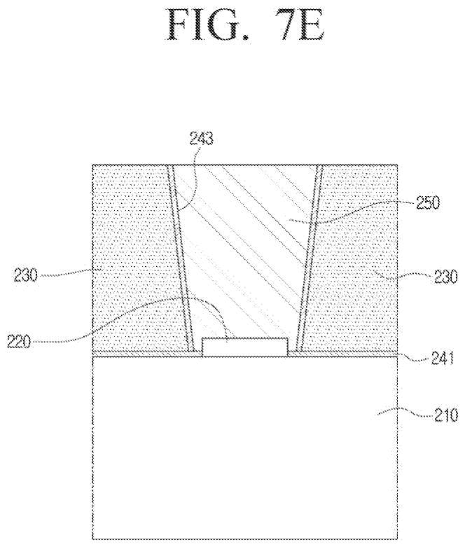

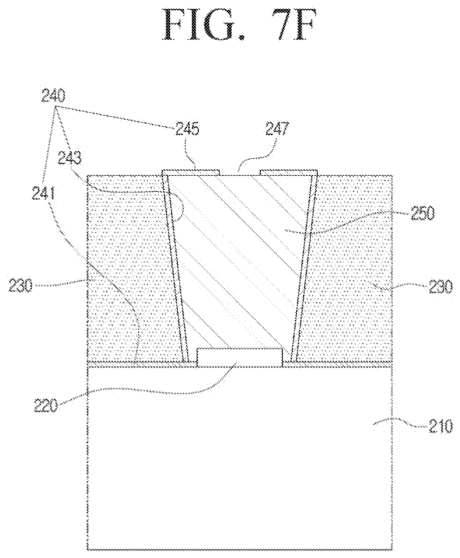

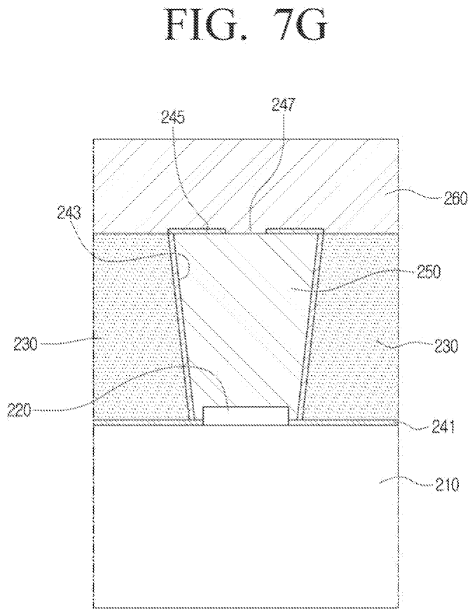

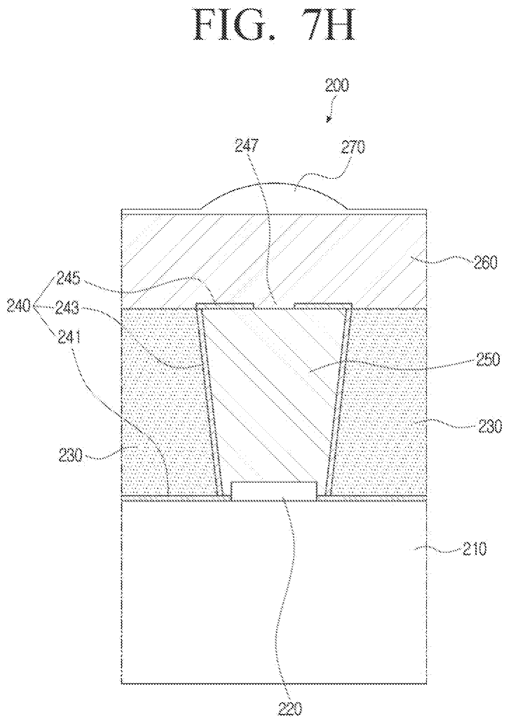

According to one or more embodiments, the partition wall 230 having a predetermined height may be disposed on the substrate 210. The partition wall 230 may be formed in a grid arrangement to form a plurality of cells 231 (FIG. 7C).

According to one or more embodiments, a plurality of cells provided on the substrate 210 by the partition wall 230 are arranged one by one, and a first substrate electrode pad and a second substrate electrode pad, which are electrically connected to the first electrode and the second electrode of the light emitting diode 220, respectively, may be arranged. The first and second substrate electrode pads may be electrically connected to a TFT circuit provided on the substrate 210.

According to one or more embodiments, the partition wall 230 may include an organic material such as a polyacrylates resin, a polyimide resin, or a silica-based inorganic material. The partition wall 230 may be formed of a material having a color of a black tone having high optical density and low reflectivity to improve a contrast ratio and secure black visibility by reducing interference between adjacent light emitting diodes 220. According to one or more embodiments, a material forming the partition wall 230 may have a reflectivity of about 9% or less at an entire wavelength region (for example, 390 nm to 700 nm) of visible light. The partition wall 230 may serve as a black matrix.

According to one or more embodiments, the sub-pixel structure 200 may include a reflective layer 240 which reflects light emitted from the light emitting diode 220 and emits the light to the micro-lens 270 through the light exit portion 247. The reflective layer 240 may include a lower reflective layer 241, a side reflective layer 243, and an upper reflective layer 245.

According to one or more embodiments, the lower reflective layer 241 may be formed on the upper surface of the substrate 210 without covering the light emitting diode 220. A portion of the lower reflective layer 241 may be disposed in a cell 231 (see FIG. 7C) formed by the partition wall 230. The partition wall 230 may be disposed on the upper surface of the remaining portion of the lower reflective layer 241. The side reflective layer 243 may be formed on a side surface of the partition wall 230.

According to one or more embodiments, the upper reflective layer 245 may be formed in the opening of the cell 231, and the light exit portion 247 may be formed to allow light, reflected in the cell 231, to be emitted to the outside of the cell 231. The light exit portion 247 may have a smaller size than the opening of the cell 231. The upper reflective layer 245 may be disposed to face the light emitting diode 220, and may reflect light to the light emitting diode 220, the side reflective layer 243, or the lower reflective layer 245.

According to one or more embodiments, the reflective layer 240 may be formed of a material having a high light reflectivity. The reflective layer 240 may be a metal layer, a resin layer containing a metal oxide, or a distributed bragg reflective layer. A thickness of the reflective layer 240 covering the partition wall 230 may be approximately 100 nm to 500 nm. The metal layer may be Al, Au, Ag, Pt, Ni, Cr, Ti, or Cu. The resin layer including the metal oxide may be a resin layer including titanium oxide. A plurality of insulating layers having different refractive indexes may be repeatedly stacked several to hundreds of times, such as twice to 100 times of the distributed bragg reflective layer. The insulating layer of the distributed bragg reflective layer may be an oxide or a nitride of SiO₂, SiN, SiOxNy, TiO₂, Si₃N₄, Al₂O₃, TlN, AlN, ZrO₂, TiAlN, TiSiN or the like, or a group thereof.

Referring to FIG. 4, the light emitted from the light emitting diode 220 may be reflected in the reflective layer 240 several times, collected to the micro-lens 270 through the light exit portion 247, and then emitted to a front surface (e.g. a direction toward the incident surface of the projection lens 110). According to one or more embodiments, as to the light emitted through the light exit portion 247, the amount of light emitted to the front side becomes maximum like the Lambertian emission graph (G1) of FIG. 4.

According to one or more embodiments, the reflective layer 240 may be configured to a jar shape where the width of a portion surrounded by the reflective layer 240 is wider and the exit is narrow. Accordingly, the light widely spread in the cell 231 is emitted through the light exit portion 247, thereby having an effect of being compressed like a point light source. Therefore, the light emitted through the light exit portion 247 may face the incident surface of the project lens 110 while maintaining a narrow divergence angle toward the front surface.

Referring to FIG. 5, the width X of the light exit portion 247 may be different depending on the focal distance F of the micro-lens 270 and the distance D between the micro-lens 270 and the light exit portion 247. The width X of the light exit portion 247 may be determined by Equation 1 below.

$$X = \frac{( F - D ) \times D}{F} \qquad ( Equation 1 )$$

In a state in which the focal length F of the micro-lens is 2 μm, and the distance D between the micro-lens 270 and the light exit portion 247 is 1 μm, the width X of the light exit portion 247 may be 0.5 μm by Equation 1. The distance H from the reflective layer 240 (e.g., the upper reflective layer 245) to the upper surface of the substrate 210 may be 3 μm, and a side inclination angle α of the partition wall 230 may be 83.3°. Here, the distance H from the reflective layer 240 (e.g., the upper reflective layer 245) to the upper surface of the substrate 210 and a side inclination angle α of the partition wall 230 may be changed.

According to one or more embodiments, the light exit portion 247 may be in various shapes such as a circle, an oval, a quadrangle, or the like, when seen from the plane.

Referring back to FIG. 3, the inside of the cell 231 may be filled with a first optical layer 250 made of a transparent optical material. The first optical layer 250 may be disposed to cover both the light emitting surface 221 and the side surface 223 of the light emitting diode 220 or may cover at least the light emitting surface 221 of the light emitting diode 220. According to one or more embodiments, the first optical layer 250 may be formed of a transparent material not affecting or minimizing the transmittance, reflectivity, and refractive index of light emitted from the light emitting diode 220. Alternatively, the first optical layer 250 may adopt a material such as an optical film material capable of minimizing wasted light and improving luminance by making the light output direction directed toward the opening of the cell 231 through refraction and reflection.

The second optical layer 260 may be formed between the micro-lens 270 and the partition wall 230. The second optical layer 260 may be made of the same material as the first optical layer 250 described above.

The micro-lens 270 may be one of a plurality of micro-lenses to be included in a micro-lens array formed in a sheet form of a thin film. According to one or more embodiments, a pitch between the plurality of micro-lenses may be set to be substantially the same as a pitch between a plurality of sub-pixels provided in the display module. Accordingly, each of the plurality of micro-lenses may be arranged to correspond to one subpixel. According to one or more embodiments, the plurality of micro-lenses may have the same focal length. However, the one or more embodiments are not limited thereto, and the plurality of micro-lenses may have different focal lengths for each region, such as a central region and an edge region of the micro-lens array.

The micro-lens array may be manufactured as a sheet form as described above and then may be attached to the second optical layer 260 by a laminating method.

The micro-lens array may be manufactured by various methods without being limited to the one or more embodiments. The micro-lens array may be formed in various ways, such as a high temperature reflow method, a grayscale mask photolithography method, a molding/imprinting method, or a dry etching pattern transfer method.

The high temperature reflow method may refer to a method in which a second optical layer 260 covering the plurality of light emitting diodes are formed on a substrate where a plurality of light emitting diodes are arranged, an optical layer including a photosensitive polymer is stacked on the second optical layer 260, and cells corresponding to each micro-lens are formed on the optical layer, and when the optical layer is heated for a predetermined time, the optical layer melts into a liquid state, so that a plurality of micro-lens having a predetermined curvature are formed by surface tension. The planarization layer may include an optical material or may be an optical adhesive. The planarization layer is a material that is cured in response to light (e.g. ultraviolet) of a designated band, and may include, for example, an optical clear adhesive (OCA), an optical clear resin (OCR), or a super view resin (SVR). Alternatively, the planarization layer may include a material capable of maintaining high transparency even in the environment of high temperature or high humidity.

The grayscale mask photolithography method may refer to a method in which a mask is disposed on the second optical layer 260, and the mask is exposed and developed to form an upper surface of the second optical layer 260 into a plurality of micro-lenses.

The molding/imprinting method forms the upper surface of the second optical layer 260 into a plurality of micro-lenses by pressing the second optical layer 260 under a predetermined temperature with a stamp having a plurality of dome-shaped grooves corresponding to a plurality of micro-lenses.

The dry pattern transfer method may refer to a method of molding the optical layer into a plurality of micro-lenses through plasma etching.

Before molding a plurality of micro-lenses by the various methods described above, a process of aligning locations of the light emitting diode corresponding to each micro-lens with a location in which a plurality of micro-lenses are to be molded may be preceded.

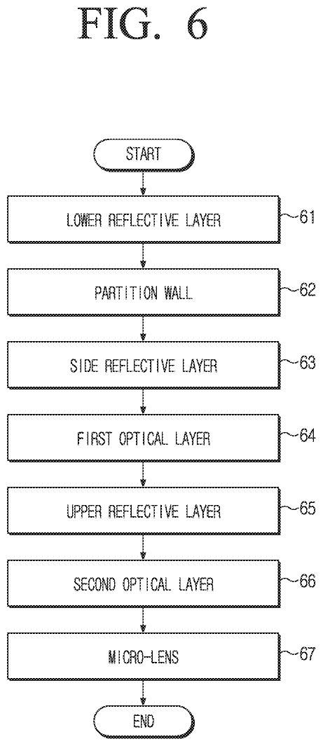

FIG. 6 is a flowchart illustrating a process of manufacturing a sub-pixel structure of a display module according to an embodiment of the disclosure, FIGS. 7A-7H are views illustrating respective manufacturing processes of a sub-pixel structure of a display module according to an embodiment of the disclosure.

Hereinafter, a process of manufacturing the sub-pixel structure 200 provided in the display module 160 according to an embodiment will be described with reference to the drawings.

Referring to FIGS. 7A and 7B, the lower reflective layer 241 is formed to have a predetermined thickness on an upper surface of the substrate 210 on which a light emitting diode 220 is mounted (61). According to one or more embodiments, the lower reflective layer 241 may be deposited on the upper surface of the substrate 210 without covering the light emitting diode 220 by sequentially performing a sputtering process, a photolithography process, and an etching process.

Referring to FIG. 7C, the partition wall 230 for forming the cell 231 surrounding the light emitting diode 220 is formed on the substrate 210 (62). According to one or more embodiments, the size of the opening formed in the upper portion of the cell 231 may be larger than the size of the light emitting diode 220.

Referring to FIG. 7D, the side reflective layer 243 is formed on a side surface of the partition wall 230 (63). The side reflective layer 243 may be formed to have a predetermined thickness on a side surface of the partition wall 230 through the deposition process.

According to one or more embodiments, the side reflective layer 243 and the lower reflective layer 241 may be formed of the same material. However, the side reflective layer 243 may be formed of different materials according to a manufacturing condition, or the like, of the display module 160.

Referring to FIG. 7E, the first optical layer 250 is formed in the cell 231 formed by the partition wall 230 (64). The first optical layer 250 may be filled with a transparent optical material up to the upper end of the cell 231. When a portion of the optical material forming the first optical layer 250 protrudes higher than the upper end of the cell 231, the protruding portion may be removed until the portion of the optical material forming the first optical layer 250 approximately matches the upper surface of the partition wall 230 through a planarization process (e.g., a chemical mechanical polishing (CMP) process).

Referring to FIG. 7F, the upper reflective layer 245 is formed at an upper portion of the planarized first optical layer 250 (65). The upper reflective layer 245 may form a metal material forming the upper reflective layer 245 with a predetermined thickness through a sputtering process or the like. According to one or more embodiments, a photolithography process and an etching process may be performed on the upper reflective layer 245 to form the light exit portion 247. A width (X, see FIG. 5) of the light exit portion 247 may be determined by Equation 1 described above.

According to one or more embodiments, the upper reflective layer 245 may be formed of the same material as the lower reflective layer 241 and the side reflective layer 243. However, the upper reflective layer 245 may be formed of different materials according to a manufacturing condition, or the like, of the display module 160.

According to one or more embodiments, the reflective layer 240 may include the lower reflective layer 241, the side reflective layer 243, and the upper reflective layer 245 sequentially formed. In addition, the lower end of the side reflective layer 243 may be connected to the upper surface of the lower reflective layer 241, and the upper reflective layer 245 on which the light exit portion 247 is formed may be connected to the upper end of the side reflective layer 243. Accordingly, the reflective layer 240 may be formed in a jar shape.

Referring to FIG. 7G, the second optical layer 260 that covers the partition wall 230, the upper reflective layer 245, and the first optical layer 250 exposed through the light exit portion 247 is formed (66). The thickness of the second optical layer 260 may correspond to a distance D (see FIG. 5) between the micro-lens 270 and the light exit portion 247.

Referring to FIG. 7H, the micro-lens 270 is disposed on the upper surface of the second optical layer 260 (67). When the micro-lens 270 is formed in a separately formed sheet form, the micro-lens 270 may be attached to the upper surface of the second optical layer 260 through a laminating process. Alternatively, the micro-lens 270 may be directly formed on an upper surface of the second optical layer 260 by methods such as a high temperature reflow method, a grayscale mask photolithography method, a molding/imprinting method, or a dry etching pattern transfer method, or the like.

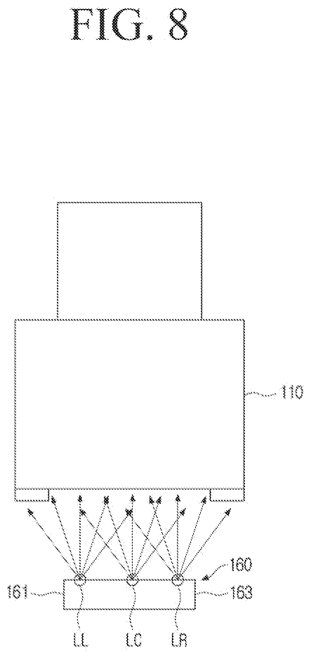

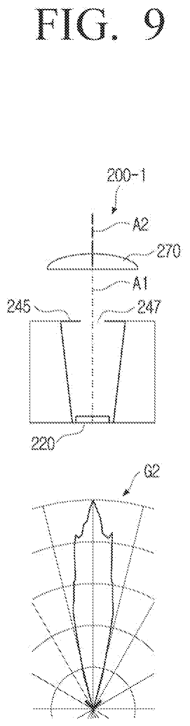

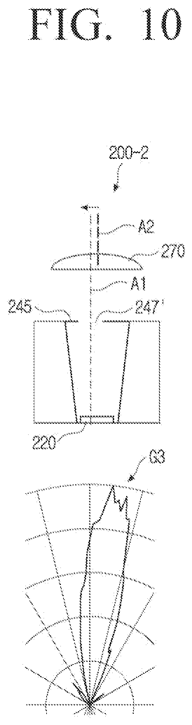

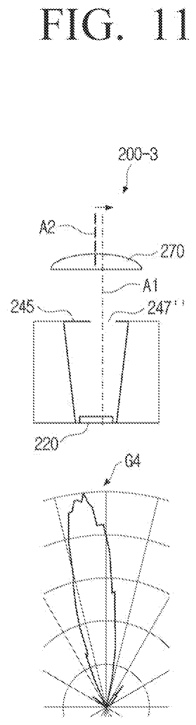

FIG. 8 is a schematic diagram illustrating a display module and a projection lens according to one or more embodiments, FIG. 9 is an enlarged view illustrating the LC portion shown in FIG. 8, FIG. 10 is an enlarged view showing the LL portion shown in FIG. 8, FIG. 11 is an enlarged view illustrating the LR portion shown in FIG. 8.

Referring to FIG. 8, light emitted from a sub-pixel located at a central portion (LC) of the display module 160 may be concentrated forward and emitted by the sub-pixel structure 200 according to one or more embodiments of the disclosure. According to one or more embodiments, a portion of the light emitted from the sub-pixel located at the left portion LL adjacent to the left end 161 of the display module 160 or the right portion LR adjacent to the right end 163 of the display module 160 may be emitted to a region outside the incident surface of the projection lens 110. Therefore, most of the total amount of light emitted from the display module 160 may be incident on the incident surface of the projection lens 110 by appropriately adjusting the direction of the light emitted according to the location of the sub-pixel on the display module 160. The wearable electronic device 101 may improve the luminance of the light emitting diode 220 and thus may clearly display an image or a video.

Controlling the direction of emitted light may be implemented as changing the position of the light exit portion 247, which is described with reference to FIGS. 9 to 11.

Referring to FIG. 9, in a sub-pixel structure 200-1 located at a central portion LC of the display module 160, a virtual first axis A1 passing through the center of the light exit portion 247 coincides with a second axis A2 passing through the center of the micro-lens 270. In this example, the center of the light emitting diode 220, the center of the light exit portion 247, and the center of the micro-lens 270 may be located in a coaxial manner. Accordingly, referring to the Lambertian emission graph (G2), the direction of the light emitted to the front surface is approximately in the direction of the first and second axes (A1, A2).

Referring to FIG. 10, in a sub-pixel structure 200-2 located at a left side portion LL of the display module 160, a the virtual first axis A1 passing through the center of a light exit portion 247′ is deflected to the left with respect to a second axis A2 passing through the center of the micro-lens 270. Although the center of the light emitting diode 220 coincides with the center of the micro-lens 270, the center of the light exit portion 247′ may be deflected from the center of the light emitting diode 220 and the center of the micro-lens 270 to the left by a predetermined distance. Referring to the Lambertian emission graph (G3), the direction of light emitting to the front is deflected approximately in the right direction.

As described above, the light emitted from the light emitting diode 220 included in the sub-pixel structure 200-2 is concentrated to the micro-lens 270 through the light exit portion 247 deflected to the left, and then is emitted to be inclined in the right direction. Therefore, it is possible to minimize the amount of light that is not incident on the incident surface of the projection lens 110 out of the left end of the incident surface of the projection lens 110 among the total amount of light emitted from the light emitting diode 220 of the sub-pixel structure 200-2.

According to one or more embodiments, in order to emit the light emitted from the light emitting diode 220 to be inclined in the right direction, the center of the micro-lens 270 may be deflected to the right from the center of the light exit portion 247′ by a predetermined distance in a state where the center of the light exit portion 247′ coincides with the center of the light emitting diode 220.

Referring to FIG. 11, in a sub-pixel structure 200-3 located at the right side LR of the display module 160, the virtual first axis A1 passing through the center of a light exit portion 247″ is deflected to the right with respect to the second axis A2 passing through the center of the micro-lens 270. According to one or more embodiments, the center of the light emitting diode 220 coincides with the center of the micro-lens 270, but the center of the light exit portion 247″ may be deflected from the center of the light emitting diode 220 and the center of the micro-lens 270 to the right by a predetermined distance. Referring to a Lambertian emission graph G4, the direction of light emitted to the front is deflected approximately in the left direction.

As described above, the light emitted from the light emitting diode 220 included in the sub-pixel structure 200-3 is concentrated to the micro-lens 270 through the light exit portion 247″ deflected to the right, and then emitted in the left direction in an inclined manner. Therefore, it is possible to minimize the amount of light that is not incident on the incident surface of the projection lens 110 out of the right end of the incident surface of the projection lens 110 among the total amount of light emitted from the light emitting diode 220 of the sub-pixel structure 200-3.

According to one or more embodiments, the center of the micro-lens 270 may be arranged to be deflected to the left from the center of the light exit portion 247″ by a predetermined distance in a state where the center of the light exit portion 247″ and the center of the light emitting diode 220 are disposed to emit the light emitted from the light emitting diode 220 in an inclined manner in the left direction.

Hereinafter, one or more embodiments of the sub-pixel structure of the display module according to the disclosure will be described with reference to the drawings.

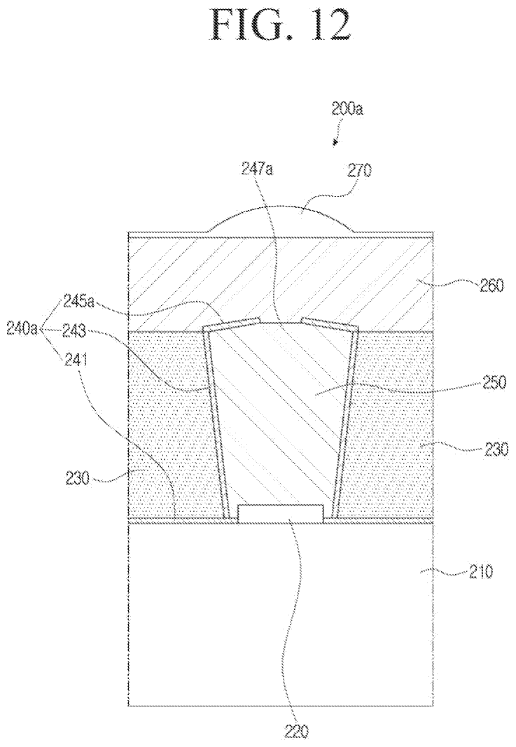

FIGS. 12 to 20 are cross-sectional views illustrating a sub-pixel structure of the display module according to one or more embodiments of the disclosure. In illustrating the sub-pixel structures shown in FIGS. 12 to 20, the same elements as those of the sub-pixel structure 200 are assigned with the same reference numerals as the sub-pixel structure 200, and a description thereof will be omitted.

Referring to FIG. 12, a sub-pixel structure 200a according to various embodiments is substantially the same as the sub-pixel structure 200 described above, but a structure in which the upper reflective layer 245a protrudes upward (a direction toward the micro-lens 270) is different from the sub-pixel structure 200 described above. According to one or more embodiments, in the upper reflective layer 245a, the side adjacent to the light exit portion 247a may be disposed at a location higher than a side adjacent to a side adjacent to the side reflective layer 243. Accordingly, the upper reflective layer 245a may be disposed to be inclined upward toward the light exit portion 247a.

According to one or more embodiments, the reflective layer 240a may maintain an approximate jar shape, as the width of the light exit portion 247a is narrower than the width inside the cell 231 to which the light is reflected. Accordingly, most of the light emitted through the light exit portion 247a may be concentrated and incident on the micro-lens 270.

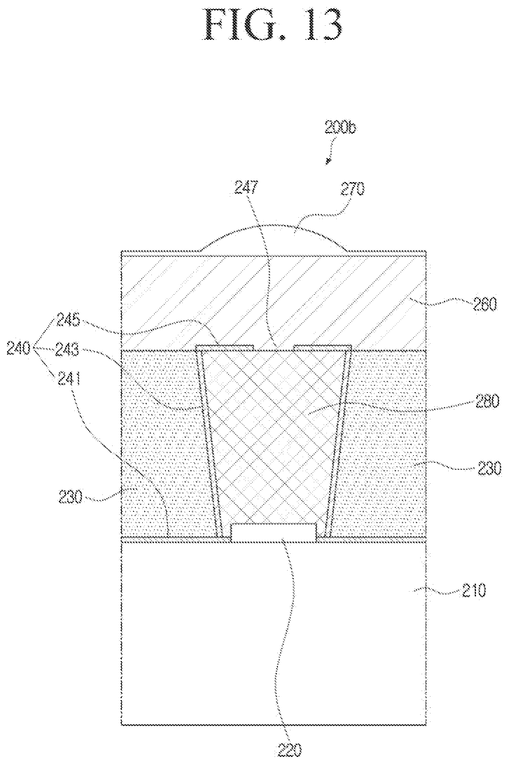

Referring to FIG. 13, in the sub-pixel structure 200b according to one or more embodiments, the space surrounded by the reflective layer 240 may be filled with a color conversion layer 280 instead of the first optical layer 250. According to one or more embodiments, the color conversion layer 280 may include a quantum dot and a photosensitive resin. According to one or more embodiments, the quantum dot may absorb incident light of the light emitting diode 220 and isotropically emit light having a wavelength of a band different from that of the incident light. The photosensitive resin may be formed of a material having light transmittance, and may be formed of a silicone resin, an epoxy resin, an acrylate, a siloxane-based, or a light-transmissive organic material. A plurality of quantum dots included in the color conversion layer 280 may improve light amount further while functioning as a point light source, respectively.

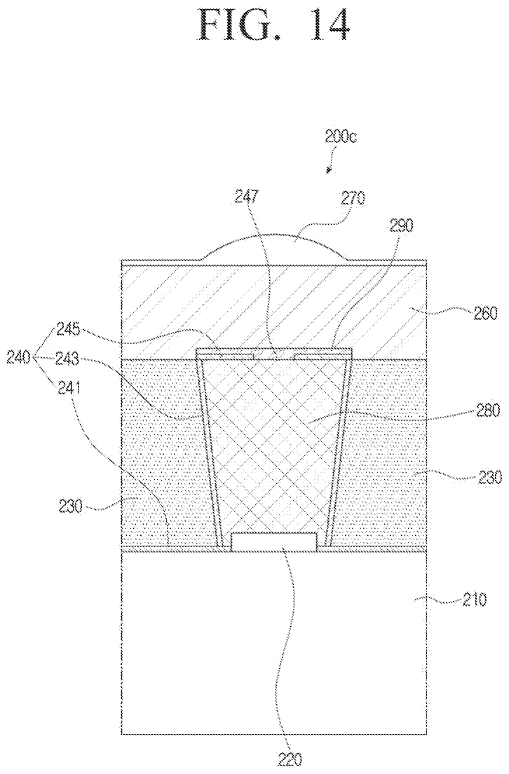

Referring to FIG. 14, the sub-pixel structure 200c according to one or more embodiments may have a structure in which a color filter layer 290 is further added in the sub-pixel structure 200b described above. The color filter layer 290 may be an organic material including a dye or a pigment. According to one or more embodiments, the color filter layer 290 may be laminated on the color conversion layer 280. The color filter layer 290 may be formed not only on the upper surface of the color conversion layer 280 but also on the upper surface of the upper reflective layer 245. The color filter layer 290 may block leakage light that is not completely converted by the color conversion layer 280.

According to one or more embodiments, light emitted from a color conversion layer 280 is reflected by the reflective layer 240 inside the cell 231, emitted through the light exit portion 247, and then incident to the micro-lens 270 via the color filter layer 290.

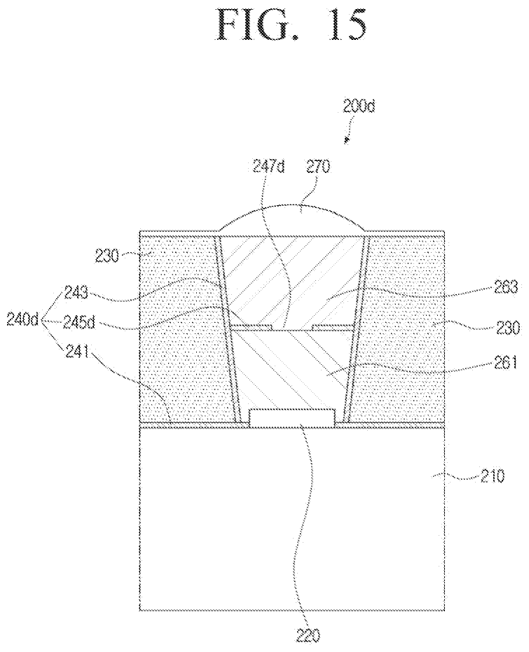

Referring to FIG. 15, the sub-pixel structure 200d according to one or more embodiments is substantially the same as the sub-pixel structure 200 described above, and the locations of the upper reflective layer 245d forming the reflective layer 240d are different. According to one or more embodiments, the upper reflective layer 245d may be disposed lower than the upper end of the side reflective layer 243. The upper reflective layer 245d having the light exit portion 247d may be formed on the first optical layer 261. The second optical layer 263 may be formed on the upper surface of the first optical layer 261 to cover the upper reflective layer 245d.

According to one or more embodiments, the upper reflective layer 245d may be disposed downward by a distance corresponding to the thickness of the second optical layer 260 of the sub-pixel structure 200 described above. The micro-lens 270 may be disposed below the location of the micro-lens 270 of the sub-pixel structure 200 described above in consideration of the height of the upper reflective layer 245d. The location of the micro-lens 270 is in consideration of the focal length F and the distance between the micro-lens 270 and the light exit portion 247d.

According to one or more embodiments, the micro-lens 270 of the sub-pixel structure 200d may be seated on the upper surface of the partition wall 230 and the upper surface of the second optical layer 263. The upper surface of the second optical layer 263 may be formed to a height corresponding to the height of the upper surface of the partition wall 230. Accordingly, a surface on which the micro-lens 270 is seated may be a flat surface on the whole.

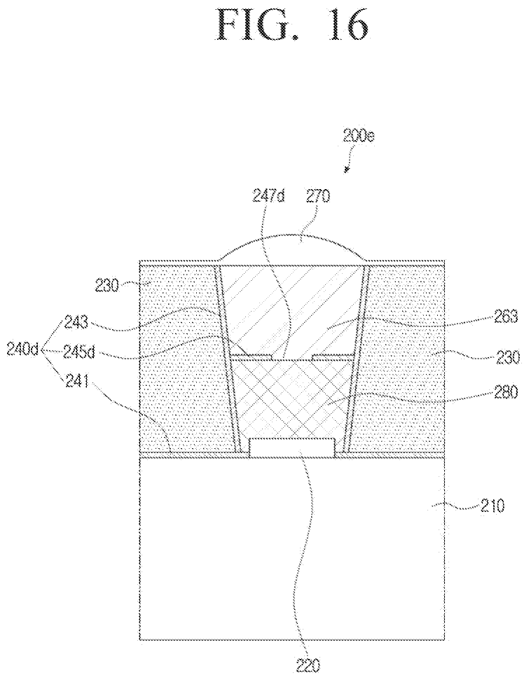

Referring to FIG. 16, the sub-pixel structure 200e according to the one or more embodiments may be a structure in which the first optical layer 261 is replaced with the color conversion layer 280 in the sub-pixel structure 200d described above.

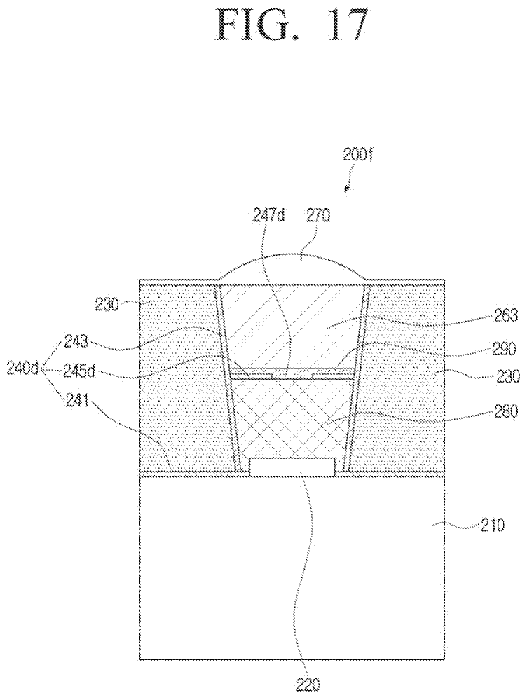

Referring to FIG. 17, a sub-pixel structure 200f according to one or more embodiments may have a structure in which a color filter layer 290 is added to the aforementioned sub-pixel structure 200e. The color filter layer 290 may be laminated on the color conversion layer 280 corresponding to the light exit portion 247d, the color filter layer 290 may be formed not only on an upper surface of the color conversion layer 280 but also on the upper surface of the upper reflective layer 245d.

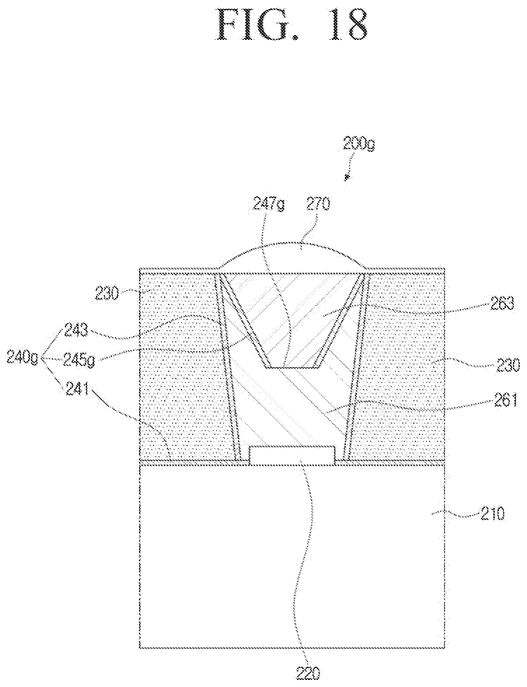

Referring to FIG. 18, the sub-pixel structure 200g according to one or more embodiments is mostly the same as the sub-pixel structure 200 described above, but the structure in which the upper reflective layer 245g is not formed to be horizontal and protrudes downward (e.g. in a direction toward the light emitting diode 220) is different from the sub-pixel structure 200 described above. According to one or more embodiments, in the upper reflective layer 245g, a side adjacent to the light exit portion 247g may be disposed lower than a side adjacent to the side reflective layer 243. Accordingly, the upper reflective layer 245g may be disposed to be inclined downward toward the light exit portion 247g. Because the width of the light exit portion 247g is narrower than the lower width of the part surrounded by the reflective layer 240g, most of the light emitted through the light exit portion 247g may be mainly concentrated on the micro-lens 270 and incident.

Accordingly, the light exit portion 247g may be located at a height lower than the height of the light exit portion 247 of the sub-pixel structure 200 described above. For example, the light exit portion 247g may be disposed downward by a distance corresponding to the thickness of the second optical layer 260 of the sub-pixel structure 200 described above. The first optical layer 261 may be formed to fill a space surrounded by the reflective layer 240g. The second optical layer 263 may be formed on the upper surface of the first optical layer 261 and the upper surface of the upper reflective layer 245g. The upper surface of the second optical layer 263 may be located at the same height as the upper surface of the partition wall 230.

According to one or more embodiments, the micro-lens 270 applied to the sub-pixel structure 200g may be disposed below the location of the micro-lens 270 of the sub-pixel structure 200 described above in consideration of the height of the light exit portion 247g. The location of the micro-lens 270 considers the distance between the focal length F and the micro-lens 270 and the light exit portion 247g.

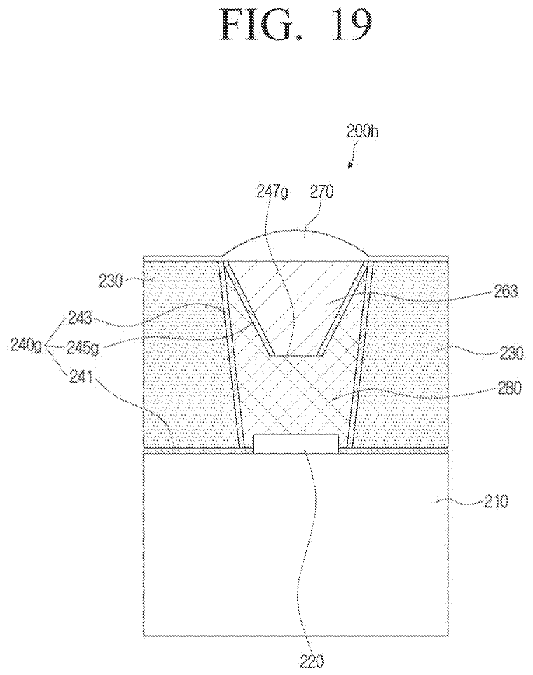

Referring to FIG. 19, the sub-pixel structure 200h according to one or more embodiments may be a structure in which the first optical layer 261 is replaced with the color conversion layer 280 from the sub-pixel structure 200g described above.

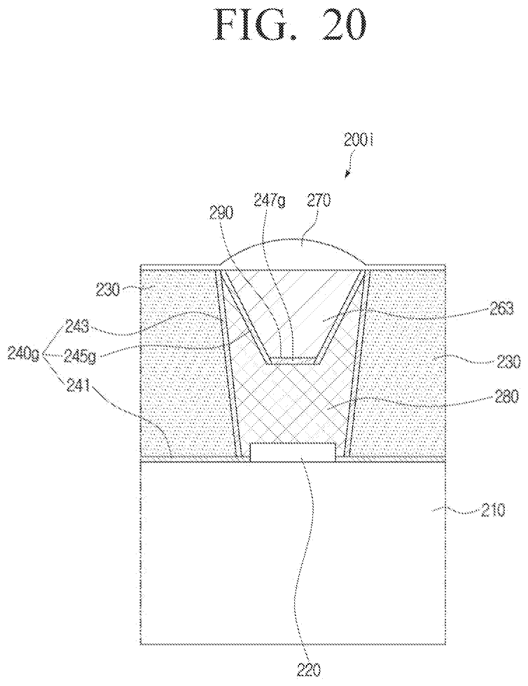

Referring to FIG. 20, a sub-pixel structure 200i according to one or more embodiments may have a structure in which the color filter layer 290 is added to the aforementioned sub-pixel structure 200h. The color filter layer 290 may be laminated on the upper surface of the color conversion layer 280 corresponding to the light exit portion 247g.

FIGS. 21 to 24 are cross-sectional views illustrating a structure of a pixel unit of a display module according to one or more embodiments.

Referring to FIG. 21, the display module 160 according to one or more embodiments may include a plurality of sub-pixel structures 201, 202, and 203 constituting one pixel unit. The first sub-pixel structure 201 may emit blue light, the second sub-pixel structure 202 may emit red light, and the third sub-pixel structure 203 may emit green light.

The first to third sub-pixel structures 201, 202, 203 all may have the same structure. The first to third sub-pixel structures 201, 202, 203 may be configured to be the same as the sub-pixel structure 200 illustrated in FIG. 3.

According to one or more embodiments, each light emitting diode 221, 222, 223 disposed in each of the sub-pixel structures 201, 202, 203 emits light of different colors. According to one or more embodiments, the light emitting diode 221 of the first sub-pixel structure 201 may be a micro LED emitting blue light, the light emitting diode 222 of the second sub-pixel structure 202 may be a micro LED emitting red light, and the light emitting diode 223 of the third sub-pixel structure 203 may be a micro LED emitting green light.

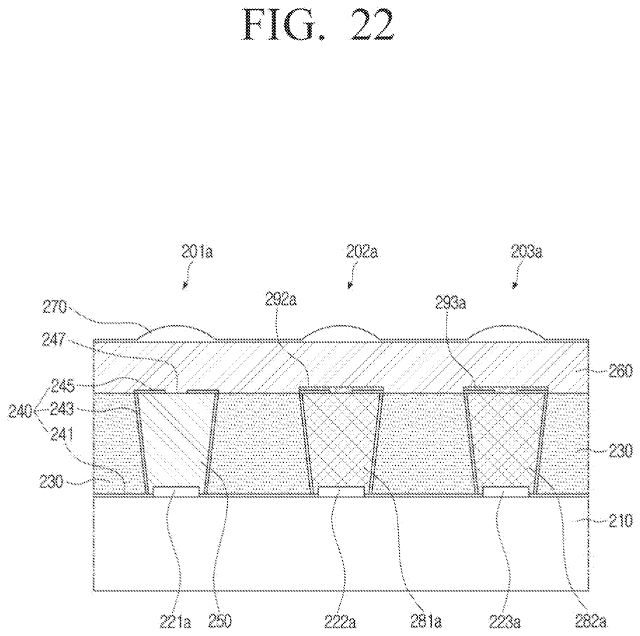

Referring to FIG. 22, the first to third sub-pixel structures 201a, 202a, 203a in a pixel unit according to one or more embodiments may apply light emitting diodes 221a, 222a, 223a emitting the light (e.g., blue light) of the same color.

According to one or more embodiments, the first to third sub-pixel structures 201a, 202a, 203a may adopt other structures to emit light of different colors. According to one or more embodiments, the first sub-pixel structure 201a may be configured differently from the second and third sub-pixel structures 202a, 203a, and the second and third sub-pixel structures 202a, 203a may be the same.

According to one or more embodiments, the first sub-pixel structure 201a may be configured to be the same as the sub-pixel structure 200 illustrated in FIG. 3, and the second and third sub-pixel structures 202a, 203a may be configured to be the same as the sub-pixel structure 200c illustrated in FIG. 14.

According to one or more embodiments, the second sub-pixel structure 202a may apply a red color conversion layer 281a and a red color filter layer 292a to emit red light. In addition, the third sub-pixel structure 203a may apply a green color conversion layer 282a and a green color filter layer 293a to emit green light.

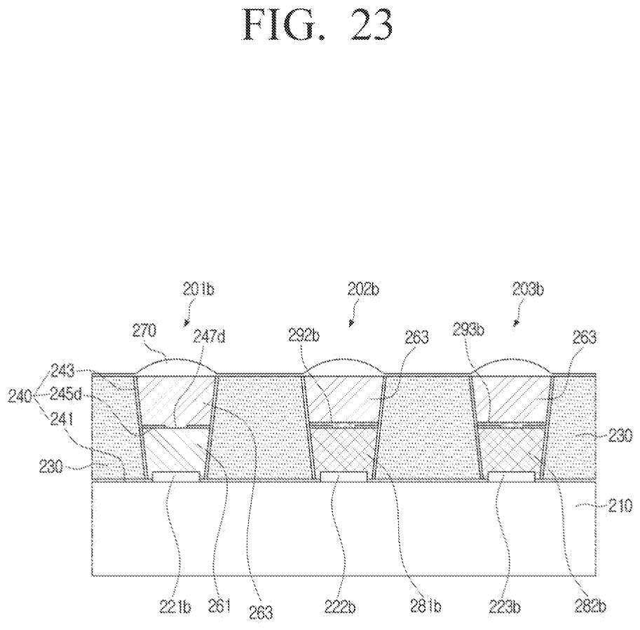

Referring to FIG. 23, the first to third sub-pixel structures 201b, 202b, 203b in the pixel unit according to the one or more embodiments all may apply light emitting diodes 221b, 222b, 223b emitting the light (e.g., blue light) of the same color.

According to one or more embodiments, the first to third sub-pixel structures 201b, 202b, 203b may adopt different structures to emit light of different colors. According to one or more embodiments, the first sub-pixel structure 201b may be configured differently from the second and third sub-pixel structures 202b, 203b, and the second and third sub-pixel structures 202b, 203b may be the same.

According to one or more embodiments, the first sub-pixel structure 201b may be configured to be the same as the sub-pixel structure 200d illustrated in FIG. 15, and the second and third sub-pixel structures 202b, 203b may be configured to be the same as the sub-pixel structure 200f illustrated in FIG. 17.

According to one or more embodiments, the second sub-pixel structure 202b may apply a red color conversion layer 281b and a red color filter layer 292b that may emit a red color light. In addition, the third sub-pixel structure 203b may apply the green color conversion layer 282b and the green color filter layer 203b that may emit a green color light.

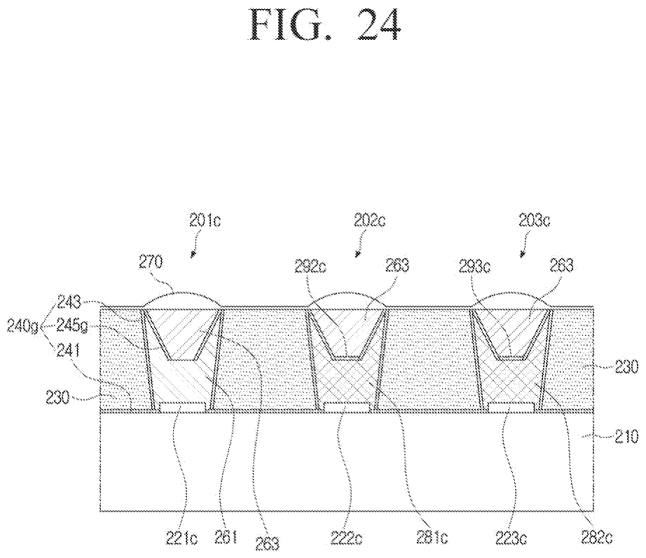

Referring to FIG. 24, the first to third sub-pixel structures 201c, 202c, 203c in a pixel unit according to one or more embodiments may apply the light emitting diodes 221c, 222c, 223c emitting the light of the same color (e.g., blue light).

According to one or more embodiments, the first to third sub-pixel structures 201c, 202c, 203c may adopt different structures to emit light of different colors. According to one or more embodiments, the first sub-pixel structure 201c may be configured differently from the second and third sub-pixel structures 202c, 203c, and the second and third sub-pixel structures 202c, 203c may be made the same.

According to one or more embodiments, the first sub-pixel structure 201c may be configured to be the same as the sub-pixel structure 200g illustrated in FIG. 18, and the second and third sub-pixel structures 202c, 203c may be configured to be the same as the sub-pixel structure 200i illustrated in FIG. 20.

According to one or more embodiments, the second sub-pixel structure 202c may apply a red color conversion layer 281c and a red color filter layer 292c to emit red light. In addition, the third sub-pixel structure 203c may apply a green color conversion layer 282c and a green color filter layer 293c to emit green light.

The disclosure is not limited to the one or more embodiments of the pixel unit described in FIGS. 21 to 24, and it is possible to combine various sub-pixel structures according to different colors which a plurality of sub-pixel structures constituting a pixel unit should emit, respectively.

According to one or more embodiments, when an end surface of a cell provided by a partition wall is formed in an approximately jar shape, an upper reflective layer may be omitted or the entire reflective layer may be omitted.

The display module 160 according to one or more embodiments may concentrate light emitted from a light emitting diode toward a front surface without spreading. The wearable electronic device 101 to which the display module 160 is applied may provide a clear image and a video to the eyes of a user by using high-luminance light emitted from the display module 160.

The display module 160 according to one or more embodiments may include the substrate 210, a plurality of light emitting diodes 220 mounted on a surface of the substrate, and a plurality of sub-pixel structures 200 comprising a plurality of light emitting diodes one by one. According to one or more embodiments, each sub-pixel structure may include the partition wall 230 formed on a surface of the substrate and configured to form a plurality of cells surrounding each of the plurality of light emitting diodes, the reflective layer 240 formed on each cell and comprising the light exit portion 247 to open a part of an opening of the cell, and the micro-lens 270 disposed on a location corresponding to the light exit portion and configured to concentrate light emitted from the light exit portion. According to one or more embodiments, the width of the light exit portion 247 may be less than the width of a space formed by the partition wall 230.

According to one or more embodiments, the first axis A1 passing through the center of the light exit portion 247 and the second axis A2 passing through the center of the micro-lens 270 may be disposed in a coaxial manner.

According to one or more embodiments, the first axis A1 passing through the center of the light exit portion 247 and the second axis A2 passing through the center of the micro-lens 270 may be disposed in parallel with each other, and the center of the light exit portion may be deflected with respect to the center of the micro-lens.

According to one or more embodiments, the center of the light emitting diode corresponding to the center of the micro-lens 270 may be coaxially disposed.

According to one or more embodiments, the center of the light emitting diode 220 corresponding to the center of the light exit portion 247 may be coaxially disposed.

According to one or more embodiments, the first optical layer 250 may be disposed in a space formed by the reflective layer, and the second optical layer 260 may be disposed between the micro-lens and the partition wall.

According to one or more embodiments, the color conversion layer 280 may be disposed in a space formed by the reflective layer, and the optical layer 260 may be disposed between the micro-lens and the partition wall.

According to one or more embodiments, the color conversion layer 280 may be exposed by the light exit portion 247, and the color filter layer 290 may be disposed on an upper surface of the color conversion layer corresponding to the light exit portion.

According to one or more embodiments, the reflective layer may include the lower reflective layer 241 disposed on an upper surface of the substrate, the side reflective layer 243 disposed on a side surface of the partition wall, and the upper reflective layer 245 configured to form the light exit portion.

According to one or more embodiments, the upper reflective layer 245 may be disposed at a height corresponding to an opening of the cell 231.

According to one or more embodiments, the upper reflective layer 245a may upwardly protrude toward the micro-lens 270, and the light exit portion 247a may be disposed at a location higher than the height of the opening of the cell 231.

According to one or more embodiments, the upper reflective layer 245g may downwardly protrude toward the light emitting diode 220, and the light exit portion 247g may be disposed at a location lower than the height of the opening of the cell 231.

According to one or more embodiments, the upper reflective layer 245d may be disposed at a location lower than the opening of the cell 231.

According to one or more embodiments, a plurality of cells comprise a plurality of sub-pixel structures 201, 202, 203 in a pixel unit, and light emitting diodes 221, 222, 223 respectively disposed in the plurality of sub-pixel structures may emit light of different colors.

According to one or more embodiments, a plurality of cells include a plurality of sub-pixel structures 201a, 202a, 203a in a pixel unit, light emitting diodes 221a, 222a, 223a respectively disposed in the plurality of sub-pixel structures may emit light of a same color, and a part of the plurality of sub-pixel structures further may include color conversion layers 281, 282, 281a, 281b, 281c, 282a, 282b, 282c to convert color of the light emitted from the light emitting device.

According to one or more embodiments, the sub-pixel structure including the color conversion layers 281, 282, 281a, 281b, 281c, 282a, 282b, 282c may further include color filter layers 292a, 292b, 292c, 293a, 293b, 293c for filtering light emitted from the color conversion layer.

According to one or more embodiments, the partition wall 230 is formed of a material having a black color and thus may perform a role of a black matrix.

The wearable electronic device 101 according to the one or more embodiments of the disclosure may include the display module 160 including a substrate, a plurality of light emitting diodes mounted on one surface of the substrate, a partition wall formed on one surface of the substrate to form a plurality of cells respectively surrounding the plurality of light emitting diodes, a reflective layer having the light exit portion 247 formed in each cell and partially opening the opening of the cell, and the micro-lens 270 corresponding to a light exit portion having a width smaller than the width of the space formed by the partition wall, the projection lens 110 concentrating light emitted from the display module, and the diffraction optical member 111 for receiving the light emitted from the projection lens from one side and emitting the light to the other side.

According to one or more embodiments, the sub-pixel structure located in the middle area of the display module 160 provided in the wearable electronic device 101 may be disposed in a coaxial manner with the center of the micro-lens 270 corresponding to the center of the light exit portion 247.

According to one or more embodiments, a sub-pixel structure located in an area adjacent to an edge of the display module 160 provided in the wearable electronic device 101 may be disposed to be deflected with respect to the center of the micro-lens 270 corresponding to the center of the light exit portion 247.

The one or more embodiments of the disclosure have been described individually, but each embodiment does not necessarily have to be implemented alone, and the configuration and operation of each embodiment may be implemented in combination with at least one other embodiment.

While the disclosure has been illustrated and described with reference to one or more embodiments, it will be understood that the one or more embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiments described herein may be used in conjunction with any other embodiments described herein.

What is claimed is:

1. A display module comprising:
a substrate;
a plurality of light emitting diodes mounted on a surface of the substrate;
a partition wall formed on the surface of the substrate and configured to form a plurality of cells surrounding each of the plurality of light emitting diodes;
a reflective layer formed on each of the plurality of cells, the reflective layer comprising a light exit portion forming an opening of each of the plurality of cells, and the light exit portion is configured to emit light from the plurality of light emitting diodes; and
a micro-lens disposed at a location corresponding to the light exit portion and configured to concentrate light emitted from the light exit portion,
wherein a width of the light exit portion is less than a width of a space formed by the partition wall.

2. The display module of claim 1, wherein a center of the light exit portion and a center of the micro-lens are coaxially disposed.

3. The display module of claim 1, wherein a center of the light exit portion is deflected with respect to a center of the micro-lens.

4. The display module of claim 3, wherein the center of each light emitting diode of the plurality of light emitting diodes and the center of the micro-lens are coaxially disposed.

5. The display module of claim 3, wherein the center of each light emitting diode of the plurality of light emitting diodes and the center of the light exit portion are coaxially disposed.

6. The display module of claim 1, further comprising a first optical layer disposed in a space formed by the reflective layer, and a second optical layer disposed between the micro-lens and the partition wall.

7. The display module of claim 1, further comprising a color conversion layer disposed in a space formed by the reflective layer, and an optical layer disposed between the micro-lens and the partition wall.

8. The display module of claim 7, further comprising:
a color filter layer,
wherein the color conversion layer is exposed by the light exit portion, and the color filter layer is disposed on an upper surface of the color conversion layer corresponding to the light exit portion.

9. The display module of claim 1, wherein the reflective layer comprises:
a lower reflective layer disposed on an upper surface of the substrate;
a side reflective layer disposed on a side surface of the partition wall; and
an upper reflective layer configured to form the light exit portion.

10. The display module of claim 9, wherein the upper reflective layer is disposed at a height corresponding to an opening of a cell of the plurality of cells.

11. The display module of claim 10, wherein the upper reflective layer upwardly protrudes toward the micro-lens, and the light exit portion is disposed at a location higher than the height of the opening of a cell of the plurality of cells.

12. The display module of claim 10, wherein the upper reflective layer downwardly protrudes toward the light emitting diode of the plurality of light emitting diodes, and the light exit portion is disposed at a location lower than the height of the opening of a cell of the plurality of cells.

13. The display module of claim 9, wherein the upper reflective layer is disposed at a location lower than the opening of a cell of the plurality of cells.

14. The display module of claim 1, wherein the plurality of cells comprise a plurality of sub-pixel structures constituting a pixel unit, and each of the light emitting diodes of the plurality of light emitting diodes are respectively disposed in the plurality of sub-pixel structures and are configured to emit light of different colors.

15. The display module of claim 14, wherein the plurality of cells comprise a plurality of sub-pixel structures constituting a pixel unit,
each of the light emitting diodes of the plurality of light emitting diodes respectively disposed in the plurality of sub-pixel structures are configured to emit light of a same color, and
a part of the plurality of sub-pixel structures further comprises a color conversion layer configured to convert color of the light emitted from each light emitting diode of the plurality of light emitting diodes.
